(19) United States
(12) Patent Application Publication
(10) Pub. No.: US 2026/0334197 A1
(43) Pub. Date: Oct. 22, 2026

(54) SEMICONDUCTOR SUBSTRATE STRUCTURE AND DEVICE

(71) Applicant: SHANGHAI INSTITUTE OF MICROSYSTEM AND INFORMATION TECHNOLOGY, CHINESE ACADEMY OF SCIENCES, Shanghai (CN)

(72) Inventors: Zhenyu WU, Shanghai (CN); Lihao WANG, Shanghai (CN); Yongquan SU, Shanghai (CN); Yichen LIU, Shanghai (CN)

(73) Assignee: SHANGHAI INSTITUTE OF MICROSYSTEM AND INFORMATION TECHNOLOGY, CHINESE ACADEMY OF SCIENCES, Shanghai (CN)

(21) Appl. No.: 19/109,571

(22) PCT Filed: Jan. 17, 2023
(86) PCT No.: PCT/CN2023/072523

§ 371 Date: Mar. 7, 2025

(30) Foreign Application Priority Data
Sep. 9, 2022 (CN) 202211104825.9

(51) Int. Cl. H10W 20/20; B81B 7/00; H10W 10/20

(52) U.S. Cl. CPC H10W 20/213; B81B 7/0006; H10W 10/20; H10W 20/2125; H10W 20/215; B81B 2203/0315; B81B 2203/04

(57) ABSTRACT

A semiconductor substrate structure and device, including a substrate, conductive pillars, lateral insulating layers, and vertical insulating layers. Vertical electrical conduction can be achieved through the conductive pillars, and electrical insulation can be achieved through the lateral and vertical insulating layers; the semiconductor substrate structure of the present disclosure can achieve 3D interconnections, and it can serve as a substrate structure for integrated circuit devices to achieve isolation between circuit element structures, reduce parasitic capacitance between transistors or leads, and enhance the radiation resistance of the devices; the structure can also be used in the design of MEMS devices to achieve electrical lead-out of the devices, simplify device packaging structures, and enhance array capabilities of the devices; additionally, the structure can be used in monolithic integrated devices like CMOS-MEMS to improve device integration, reduce crosstalk between IC circuits and MEMS devices, and increase substrate utilization.

### FIELD OF TECHNOLOGY

The present disclosure belongs to the field of semiconductor technology, and relates to a semiconductor substrate structure and device.

### BACKGROUND

In the semiconductor field, single-crystal silicon is typically used as a substrate material, and then various semiconductor devices are fabricated based on this single-crystal silicon substrate. However, single-crystal silicon substrates also have some technical limitations. Therefore, Silicon-on-Insulator (SOI) substrates, which have an intermediate insulating layer, are widely used as functional substrates in integrated circuits (ICs) to provide electrical isolation layers, reduce device leakage currents, enhance device radiation characteristics, and in MEMS processes, provide etch stop layers and increase process uniformity. However, conventional SOI substrates only contain horizontal insulating layers and cannot achieve vertical electrical conduction.

With increasing integration density of semiconductor devices, more and more semiconductor devices require vertical electrical interconnection, which means that elements or structures located on both sides of the substrate need to be electrically interconnected through the substrate itself. Related methods for vertical electrical interconnection typically involve using Through-Silicon-Via (TSV) substrates. However, most related TSV technologies achieve this by etching deep holes in the substrate and filling them with electroplated metal. Such TSV substrates are only suitable for low-temperature processes below 500 °C, mostly used as electrical packaging substrates, and are not compatible with front-end high-temperature processes above 700 °C; additionally, such TSV substrates only contain vertical insulation and conduction structures and do not have the advantages of SOI substrates.

### SUMMARY

In view of the above-described disadvantages of the related technology, the purpose of the present disclosure is to provide a semiconductor substrate structure and device to address the limitations of substrate applications in related technologies.

To achieve the above objectives and other related purposes, the present disclosure provides a semiconductor substrate structure, which includes:
a substrate, wherein the substrate includes a first surface and a second surface opposite to each other;
conductive pillars, wherein the conductive pillars penetrate the substrate from the first surface to the second surface;
lateral insulating layers, wherein the lateral insulating layers are located in the substrate and are arranged at intervals or continuously along a lateral direction of the substrate;
vertical insulating layers, wherein the vertical insulating layers are located in the substrate and are arranged at intervals along a vertical direction of the substrate, penetrating the substrate from the first surface to the second surface and surrounding the conductive pillars, with an interval between each of the vertical insulating layers and each of the lateral insulating layers.

Optionally, a material of the conductive pillars includes one or more of single-crystal silicon, polysilicon, silicon dioxide, and silicon nitride; a resistivity of the conductive pillars is less than 5×10⁻³Ω·cm.

Optionally, a material of the substrate includes one or more of single-crystal silicon, polycrystalline silicon, silicon carbide, diamond, and Group III-V semiconductors; a thickness of the substrate ranges from 100 μm to 800 μm.

Optionally, an angle between the lateral insulating layers and the vertical insulating layers ranges from 30° to 150°.

Optionally, a cross-sectional shape of each of the conductive pillars includes one or more of circle, ellipse, arc, and polygon; a cross-sectional shape of each of the vertical insulating layers includes one or more of circle, ellipse, arc, and polygon; a cross-sectional shape of each of the lateral insulating layers includes one or more of circle, ellipse, arc, and polygon.

Optionally, a material of the lateral insulating layers includes one or more of oxides, nitrides, carbides, and polymers; a material of the vertical insulating layers includes one or more of oxides, nitrides, carbides, and polymers; the oxides include silicon dioxide, the nitrides include silicon nitride, and the carbides include silicon carbide.

Optionally, an applicable process temperature of the semiconductor substrate structure ranges from 25 °C to 1200 °C.

Optionally, in any of the above semiconductor substrate structures, the lateral insulating layers are composed of insulating medium shells and cavities.

The present disclosure also provides a semiconductor device, which includes any of the above-mentioned semiconductor substrate structures.

Optionally, the semiconductor device includes one or more of MEMS devices or integrated circuit devices.

As described above, the semiconductor substrate structure of the present disclosure includes the substrate, the conductive pillars, the lateral insulating layers, and the vertical insulating layers. The conductive pillars enable vertical electrical conduction between the upper and lower surfaces of the substrate. The lateral insulating layers isolate the element structures on the upper and lower surfaces of the substrate, and the vertical insulating layers electrically insulate the conductive pillars from the substrate.

The semiconductor substrate structure of the present disclosure can achieve 3D interconnection, with advantages such as strong process compatibility, flexible design, and suitability for high-temperature processes. The structure can serve as a substrate structure for integrated circuit devices, such as CMOS, to achieve isolation between circuit element structures, reduce parasitic capacitance between transistors or leads, and enhance the radiation resistance of the devices; the structure can also be used in the design of MEMS devices to achieve electrical lead-out, simplify device packaging structures, and enhance the array capabilities of the devices; additionally, the structure can be used in monolithic integrated devices such as CMOS-MEMS to improve device integration, reduce crosstalk between integrated circuits and MEMS devices, and increase substrate utilization.

### BRIEF DESCRIPTION OF THE DRAWINGS

FIG. 1 shows a schematic structural diagram of a semiconductor substrate structure provided in Embodiment 1 of the present disclosure.

FIG. 2 shows a partial top view schematic structural diagram of a semiconductor substrate structure in FIG. 1.

FIG. 3 shows another partial top view schematic structural diagram of a semiconductor substrate structure in FIG. 1.

FIG. 4 shows a schematic structural diagram of a semiconductor substrate structure provided in Embodiment 2 of the present disclosure.

FIG. 5 shows a schematic structural diagram of an integrated circuit device provided in Embodiment 3 of the present disclosure.

FIG. 6 shows a schematic structural diagram of a MEMS device provided in Embodiment 4 the present disclosure.

### REFERENCE NUMERALS

100 Substrate
101 Lateral insulating layers
1011 Insulating medium shells
1012 Cavities
102 Conductive pillars
103 Vertical insulating layers
110 Integrated circuit elements
111 First MEMS elements
112 Second MEMS elements
113 Redistribution layer
114 Electrical lead-out electrodes

### DETAILED DESCRIPTION

The embodiments of the present disclosure will be described below. Those skilled can easily understand advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

When describing the embodiments of the present disclosure, for better explanation, cross-sectional structural diagrams may be partially enlarged without following the general scale. Moreover, the diagrams are only examples and should not limit the scope of the present disclosure. In addition, the actual production should comprise the length, width and depth of the three-dimensional space dimensions.

For the convenience of description, spatial relation terms such as “below”, “under”, “beneath”, “on”, “above”, “up”, etc. may be used herein to describe the relationships between an element or feature and other elements or features. It will be understood that these spatial relationship terms are intended to encompass directions/orientations of the device in use or operation other than those depicted in the drawings. In addition, when a first layer is referred to as being “between” a second layer and a third layer, the first layer may be the only layer between the second and third layers, or there may more layers between the two layers. When an element is “fixed onto” or “disposed on” another element, it may be directly or indirectly on the other element. When an element is “attached to” or “connected to” another element, it may be directly or indirectly attached/connected to the other element.

Expressions such as “between . . . ” may be used herein to indicate that two endpoints of the range are included, and expressions such as “several” may be used to indicate two or more, unless explicitly and specifically qualified otherwise. In addition, the terms like “first” and “second” are used for descriptive purpose only, and are not to be construed as indicating or implying relative importance or implicitly specifying numbers of technical features indicated. Thus, features qualified with terms like “first” and “second” may explicitly or implicitly comprise one or more such features.

It should be noted that the drawings provided in this disclosure only illustrate the basic concept of the present disclosure in a schematic way, so the drawings only show the components closely related to the present disclosure. The drawings are not necessarily drawn according to the number, shape and size of the components in actual implementation; during the actual implementation, the type, quantity and proportion of each component can be changed as needed, and the components' layout may also be more complicated.

### Embodiment 1

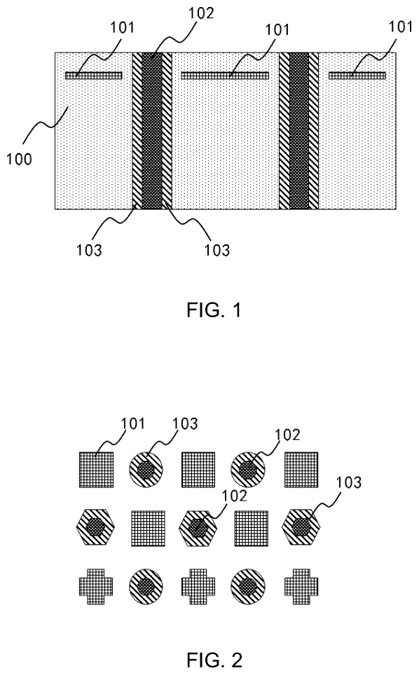

Referring to FIG. 1, this embodiment provides a semiconductor substrate structure, which includes a substrate 100, lateral insulating layers 101, conductive pillars 102, and vertical insulating layers 103.

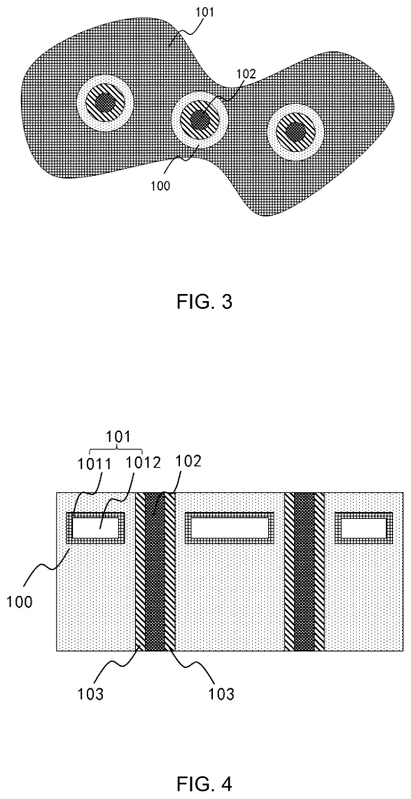

The substrate 100 includes a first surface and a second surface opposite to each other; the conductive pillars 102 penetrate the substrate 100 from the first surface to the second surface, exposing both ends of each of the conductive pillars 102. This allows vertical electrical conduction between the upper and lower surfaces of the substrate 100 through the conductive pillars 102; the lateral insulating layers 101 are located within the substrate 100 and are arranged at intervals along the lateral direction of the substrate 100, as shown in FIG. 2, or continuously arranged along the lateral direction of the substrate 100, as shown in FIG. 3. The lateral insulating layers 101 can isolate element structures on the upper and lower surfaces of the substrate 100 and define the distance between the lateral insulating layers 101 and the upper and lower surfaces of the substrate 100; the vertical insulating layers 103 are located within the substrate 100 and are arranged at intervals along the vertical direction of the substrate 100, penetrating the substrate 100 from the first surface to the second surface and surrounding the periphery of the conductive pillars 102, and the vertical insulating layers 103 can achieve electrical insulation between the conductive pillars 102 and the substrate 100. Additionally, there is an interval between each of the vertical insulating layers 103 and each of the lateral insulating layers 101, meaning the lateral insulating layers 101 and the vertical insulating layers 103 are set independently without contact. This configuration provides the semiconductor substrate structure with good mechanical and electrical performance.

As an example, the material of the substrate 100 can include one or more of single-crystal silicon, polysilicon, silicon carbide, diamond, and Group III-V semiconductors.

Specifically, the material of the substrate 100 can be selected as needed. The substrate 100 can be a single-layer substrate, such as a single-crystal silicon substrate, polysilicon substrate, silicon carbide substrate, diamond substrate, or Group III-V semiconductor substrate, or the substrate 100 can be a composite laminated substrate, which is composed of two or more different material layers stacked together. Preferably, the thickness of the substrate 100 is 100 μm to 800 μm, such as 100 μm, 200 μm, 400 μm, 600 μm, 800 μm, etc., which can be specifically selected as needed.

As an example, a material of the vertical insulating layers 101 includes one or more of oxides, nitrides, carbides, and polymers; a material of the vertical insulating layers 103 includes one or more of oxides, nitrides, carbides, and polymers; the oxides include silicon dioxide, the nitrides include silicon nitride, and the carbides include silicon carbide.

Specifically, the material of the lateral insulating layer 101 can be the same as or different from the material of the vertical insulating layer 103. The specific types, sizes, distributions, and morphologies of the lateral insulating layer 101 and the vertical insulating layer 103 can be selected as needed.

As an example, an angle between the lateral insulating layers 101 and the vertical insulating layers 103 ranges from 30° to 150°.

Specifically, to shorten the transmission path and reduce losses, it is preferred that the lateral insulating layers 101 are arranged in the horizontal direction of the substrate 100, and the vertical insulating layers 103 are arranged perpendicular to the lateral insulating layers 101, creating a perpendicular angle between the lateral insulating layers 101 and the vertical insulating layers 103. However, this is not limited to this configuration; the angle between the lateral insulating layers 101 and the vertical insulating layers 103 can also be 30°, 45°, 60°, 135°, 150°, etc., as needed. This provides a flexible 3D interconnected semiconductor substrate.

As an example, a material of the conductive pillars 102 includes one or more of single-crystal silicon, polycrystalline silicon, silicon dioxide, and silicon nitride; a resistivity of the conductive pillars is less than 5×10⁻³Ω·cm.

Specifically, the material of the conductive pillars 102 is selected to be doped silicon-based materials, which provide low resistivity to facilitate electrical connection of the conductive pillars 102. The resistivity of the conductive pillars 102 is preferably less than 5×10⁻³Ω·cm, such as 4.5×10⁻³Ω·cm, 2×10⁻³Ω·cm, 1×10⁻³Ω·cm, etc. The material of the conductive pillars 102 is selected to be doped silicon-based rather than metal, such as copper, to meet electrical connection requirements while allowing the semiconductor substrate structure to have a wide temperature adaptation range. This enables the semiconductor substrate structure to be suitable for high-temperature environments, such as semiconductor processes above 700 °C, with processing environments of 700 °C, 800 °C, 900 °C, 1000 °C, 1200 °C, etc. Certainly, the semiconductor substrate structure can also be suitable for normal or low-temperature environments, such as 25 °C, 100 °C, 200 °C, 400 °C, 500 °C, 600 °C, etc.

As an example, a cross-sectional shape of the conductive pillars 102 can include one or more of circle, ellipse, arc, and polygon; a cross-sectional shape of each of the lateral insulating layers 101 can include one or more of circle, ellipse, arc, and polygon; a cross-sectional shape of each of the vertical insulating layer 103 can include one or more of circle, ellipse, arc, and polygon.

Specifically, as shown in FIG. 2 and FIG. 3, the cross-sectional shape of the conductive pillars 102 can be circular, oval, arcuate, triangular, quadrilateral, hexagonal, etc., as needed; similarly, the cross-sectional shape of the lateral insulating layer 101 can include circular, oval, arcuate, triangular, quadrilateral, hexagonal, etc.; the cross-sectional shape of the vertical insulating layer 103 can also include circular, oval, arcuate, triangular, quadrilateral, hexagonal, etc. In this embodiment, the semiconductor substrate structure can provide a lateral isolation layer for the substrate 100 through the lateral insulating layer 101, reducing device leakage currents, enhancing device radiation characteristics, and serving as an etch stop layer to ensure etching uniformity; through the conductive pillars 102 and the vertical insulating layer 103, vertical electrical interconnection can be achieved while expanding the applicable temperature range of the semiconductor substrate structure, especially for high-temperature processes; the lateral insulating layers 101 and the vertical insulating layers 103 which are arranged at intervals also provides the semiconductor substrate structure with good mechanical and electrical performance.

### Embodiment 2

Referring to FIG. 4, this embodiment provides a semiconductor substrate structure, which mainly differs from Embodiment 1 in that the lateral insulating layers 101 are composed of insulating medium shells 1011 and cavities 1012. In this embodiment, the material and structure of the substrate 100, conductive pillars 102, and vertical insulating layers 103 in the semiconductor substrate structure can all refer to those in Embodiment 1.

The material of the insulating medium shells 1011 can be the same as that of the lateral insulating layer in Embodiment 1, such as one or more of oxides and silicon nitride. The oxides can include one or more of silicon oxide, aluminum oxide, titanium oxide, hafnium oxide, etc. The cavities 1012 can be vacuum-sealed cavities, with the vacuum degree of the cavities 1012 being set as needed. Certainly, the cavities 1012 can also be just sealed cavities or open cavities. The specific sizes, distributions, and morphologies of the insulating medium shells 1011 and the cavities 1012 can be selected as needed.

In this embodiment, based on Embodiment 1, the setting of the cavities 1012 can provide the semiconductor substrate structure with good heat dissipation channels, and the setting can also be applied in devices such as integrated circuits like CMOS and MEMS, thereby expanding the application range of the semiconductor substrate structure.

### Embodiment 3

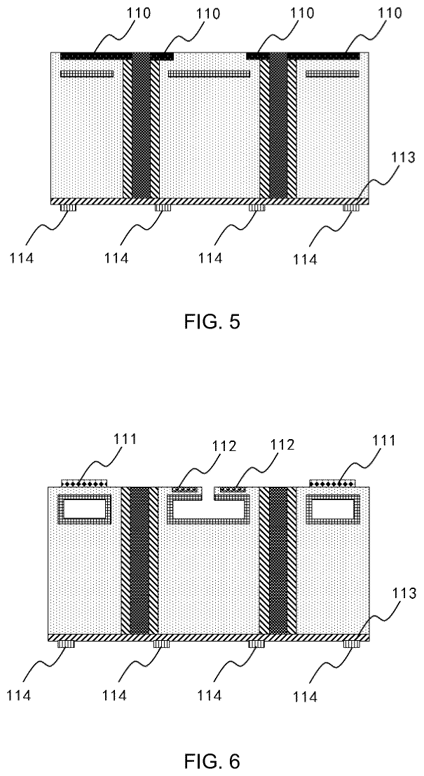

Referring to FIG. 5, this embodiment provides a semiconductor device, which uses the semiconductor substrate structure described in Embodiment 1. The semiconductor device includes the semiconductor substrate structure, integrated circuit elements 110 such as CMOS on the first surface of the substrate 100, and a redistribution layer 113 and electrical lead-out electrodes 114 electrically connected to the redistribution layer 113 on the second surface of the substrate 100, enabling vertical electrical conduction through the semiconductor substrate structure.

The types of device elements set on the semiconductor substrate structure are not limited to these examples. The device elements can include passive elements such as resistors and capacitors, active elements like MEMS elements, or combinations of integrated circuit elements and MEMS elements. The position of the redistribution layer 113 is also not limited to this configuration. For example, the redistribution layer 113 can also be set on the first surface of the semiconductor substrate structure or on both opposite surfaces of the semiconductor substrate structure as needed.

### Embodiment 4

Referring to FIG. 6, this embodiment provides a semiconductor device, which uses the semiconductor substrate structure with cavities 1012 described in Embodiment 2. The semiconductor device includes the semiconductor substrate structure, first MEMS elements 111 and second MEMS elements 112 on the first surface of the substrate 100, and a redistribution layer 113 and electrical lead-out electrodes 114 electrically connected to the redistribution layer 113 on the second surface of the substrate 100, enabling vertical electrical conduction through the semiconductor substrate structure.

The types of device elements set on the semiconductor substrate structure are not limited to these examples. The device elements can include passive elements such as resistors and capacitors, active elements like integrated circuit elements, or combinations of integrated circuit elements and MEMS elements. The position of the redistribution layer 113 is also not limited to this configuration. For example, the redistribution layer 113 can also be set on the first surface of the semiconductor substrate structure or on both opposite surfaces of the semiconductor substrate structure as needed.

In summary, the semiconductor substrate structure of the present invention includes the substrate, conductive pillars, lateral insulating layers, and vertical insulating layers. The conductive pillars enable vertical electrical conduction between the upper and lower surfaces of the substrate. The lateral insulating layers isolate element structures on the upper and lower surfaces of the substrate, and the vertical insulating layers electrically insulate the conductive pillars from the substrate.

The semiconductor substrate structure of the present disclosure can achieve 3D interconnections, with advantages such as strong process compatibility, flexible design, and suitability for high-temperature processes. The structure can serve as a substrate structure for integrated circuit devices, such as CMOS, to achieve isolation between circuit element structures, reduce parasitic capacitance between transistors or leads, and enhance the radiation resistance of the devices; the structure can also be used in the design of MEMS devices to achieve electrical lead-out, simplify device packaging structures, and enhance the array capabilities of the devices; additionally, the structure can be used in monolithic integrated devices such as CMOS-MEMS to improve device integration, reduce crosstalk between IC circuits and MEMS devices, and increase substrate utilization.”

The above-mentioned embodiments are merely illustrative of the principle and effects of the present disclosure instead of restricting the scope of the present disclosure. Any person skilled in the art may modify or change the above embodiments without violating the principle of the present disclosure. Therefore, all equivalent modifications or changes made by those who have common knowledge in the art without departing from the spirit and technical concept disclosed by the present disclosure shall be still covered by the claims of the present disclosure.

1. A semiconductor substrate structure, comprising:
a substrate, wherein the substrate comprises a first surface and a second surface opposite to each other;
conductive pillars, wherein the conductive pillars penetrate the substrate from the first surface to the second surface;
lateral insulating layers, wherein the lateral insulating layers are located in the substrate and are arranged at intervals or continuously along a lateral direction of the substrate;
vertical insulating layers, wherein the vertical insulating layers are located in the substrate and are arranged at intervals along a vertical direction of the substrate, penetrating the substrate from the first surface to the second surface and surrounding the conductive pillars, with an interval between each of the vertical insulating layers and each of the lateral insulating layers.

2. The semiconductor substrate structure according to claim 1, wherein a material of the conductive pillars comprises one or more of single-crystal silicon, polycrystalline silicon, silicon dioxide, and silicon nitride; wherein a resistivity of the conductive pillars is less than 5×10⁻³ Ω·cm.

3. The semiconductor substrate structure according to claim 1, wherein a material of the substrate comprises one or more of single-crystal silicon, polycrystalline silicon, silicon carbide, diamond, and Group III-V semiconductors; wherein a thickness of the substrate ranges from 100 μm to 800 μm.

4. The semiconductor substrate structure according to claim 1, wherein an angle between the lateral insulating layers and the vertical insulating layers ranges from 30° to 150°.

5. The semiconductor substrate structure according to claim 1, wherein a cross-sectional shape of each of the conductive pillars comprises one or more of circle, ellipse, arc, and polygon; wherein a cross-sectional shape of each of the lateral insulating layers comprises one or more of circle, ellipse, arc, and polygon; wherein a cross-sectional shape of each of the vertical insulating layers comprises one or more of circle, ellipse, arc, and polygon.

6. The semiconductor substrate structure according to claim 1, wherein a material of the lateral insulating layers comprises one or more of oxides, nitrides, carbides, and polymers; wherein a material of the vertical insulating layers comprises one or more of oxides, nitrides, carbides, and polymers; wherein the oxides comprise silicon dioxide, the nitrides comprise silicon nitride, and the carbides comprise silicon carbide.

7. The semiconductor substrate structure according to claim 1, wherein an applicable process temperature of the semiconductor substrate structure ranges from 25 °C to 1200 °C.

8. The semiconductor substrate structure according to claim 1, wherein the lateral insulating layers are composed of insulating medium shells and cavities.

9. A semiconductor device, wherein the semiconductor device comprises the semiconductor substrate structure according to claim 1.

10. The semiconductor device according to claim 9, wherein the semiconductor device comprises one or more of MEMS devices or integrated circuit devices.
